(19) United States
(12) Patent Application Publication
(10) Pub. No.: US 2017/0047535 A1
(43) Pub. Date: Feb. 16, 2017

(54) DUAL GATE DEVICE AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventor: Hongyuan XU, Shenzhen, Guangdong (CN)

(73) Assignee: Shenzhen China Star Optoelectronics Technology Co., Ltd., Shenzhen, Guangdong (CN)

(21) Appl. No.: 14/901,041

(22) PCT Filed: Apr. 21, 2015
(86) PCT No.: PCT/CN2015/077063

§ 371 Date: Dec. 27, 2015

(30) Foreign Application Priority Data
Apr. 8, 2015 (CN) 201510163163.6

(51) Int. Cl. H01L 51/05; H01L 51/00

(52) U.S. Cl. CPC H01L 51/0554; H01L 51/052; H01L 51/0096; H01L 51/0023; H01L 51/0014

(57) ABSTRACT

The embodiment of the disclosure discloses a method of manufacturing the dual gate device, comprising: forming a first metal layer on a substrate; patterning the first metal layer through a first mask to form a bottom gate electrode; coating a first organic isolation layer on the bottom gate electrode and the substrate; sputtering a second metal layer on the first organic isolation layer; patterning the second metal layer to form a source-drain electrode; disposing an organic semiconductor layer, a second organic isolation layer and a third metal layer sequentially on the source-drain electrode and the first organic isolation layer; and patterning the organic semiconductor layer, the second organic isolation layer and the third metal layer through a third mask to form a top gate electrode. The top gate electrode overlapping the source-drain electrode makes the dual gate device to reduce the device contact resistance and saves the power consumption.

This application claims the benefit of, and priority to, Chinese Patent Application No. 201510163163.6, filed Apr. 8, 2015, titled “Dual Gate Device and Manufacturing Method Thereof”, the entire contents of which are incorporated by reference herein in its entirety.

### BACKGROUND

Technical Field

The disclosure is related to the field of the electronic component, and more particularly to a dual gate device and a method of manufacturing the dual gate device.

Related Art

Thin film transistors (TFT) are switch elements of pixel units mainly used for the flat panel display device. The organic thin film transistor (OTFT) is a thin film transistor using the organic material for the semiconductor material. Due to the characteristic with well flexibility, rolling ability, lower production cost and easy carrying, the organic thin film transistors become the most promising novel array plate of the next generation of the flexible display technology.

The organic layer materials of the OTFT have two main types of polymers and small molecules. Currently, most of the mobility of the OTFT devices is low because of the limitation of the individual characteristics of the material. The mobility of the OTFT devices is hard to achieve the level of driving the organic light-emitting diode (OLED). Furthermore, the threshold voltage of the organic material is not easy to control by the material or process. It causes large increase on the operating power consumption of the device and the application of the OTFT in the display field is restricted.

### SUMMARY

The technical problem to be solved by the embodiment of the disclosure is providing a method of manufacturing the dual gate device and a dual gate device. The structure of the OTFT device adopts the dual gate structure to improve the device characteristic and achieves the purposes of reducing the threshold voltage, increasing the on-state current and reducing the off-state current. The top gate electrode overlapping the source-drain electrode makes the dual gate device to reduce the device contact resistance and to save the power consumption.

In order to solve the above technical issue, a first aspect of the embodiment of the disclosure discloses a method of manufacturing the dual gate device, comprising:

forming a first metal layer on a substrate;

patterning the first metal layer through a first mask to form a bottom gate electrode;

coating a first organic isolation layer on the bottom gate electrode and the substrate;

sputtering a second metal layer on the first organic isolation layer;

patterning the second metal layer through a second mask to form a source-drain electrode;

disposing an organic semiconductor layer, a second organic isolation layer and a third metal layer sequentially on the source-drain electrode and the first organic isolation layer; and

patterning the organic semiconductor layer, the second organic isolation layer and the third metal layer through a third mask to form a top gate electrode.

In one embodiment, the first organic isolation layer covers the bottom gate electrode; the organic semiconductor layer covers the source-drain electrode; the top gate electrode overlaps the source-drain electrode.

In one embodiment, the source-drain electrode is in the orthogonal projection area of the bottom gate electrode.

In one embodiment, the bottom gate electrode is in a middle region of an upper surface of the substrate.

In one embodiment, a surface of the organic semiconductor layer away from the source-drain electrode is a planar surface.

In one embodiment, the top gate electrode overlaps the source-drain electrode.

In one embodiment, the method of manufacturing further comprising:

coating a passivation layer on the first organic isolation layer, the organic semiconductor layer, the second organic isolation layer and the top gate electrode; wherein the passivation layer is coated on an upper surface of the first organic isolation layer away from the substrate; the passivation layer covers the organic semiconductor layer, the second organic isolation layer and the top gate electrode.

In one embodiment, the orthogonal projection area of the passivation layer and the orthogonal projection area of the substrate are the same.

In one embodiment, the substrate is made of poly ethylene naphthalate, polyethylene terephthalate or polyimide; the first metal layer, the second metal layer and the third metal layer are made of any one of gold, sliver, cooper and iron.

Another aspect of the embodiment of the disclosure discloses a dual gate device, comprising: a substrate, a bottom gate electrode, a first organic isolation layer, a source-drain electrode, an organic semiconductor layer, a second organic isolation layer and a top gate electrode, wherein:

the bottom gate electrode is located at a upper surface of the substrate;

the first organic isolation layer is located at the upper surface of the substrate and covering the bottom gate electrode;

the source-drain electrode is located at an upper surface of the first organic isolation layer of the substrate;

the organic semiconductor layer is located at the upper surface of the first organic isolation layer of the substrate and covering the source-drain electrode;

the second organic isolation layer is located at an upper surface of the organic semiconductor layer of the substrate;

the top gate electrode is located at an upper surface of the second organic semiconductor layer of the substrate.

In one embodiment, the source-drain electrode is in the orthogonal projection area of the bottom gate electrode; the upper surface of the organic semiconductor layer is a planar surface.

In one embodiment, the orthogonal projection area of the organic semiconductor layer and the orthogonal projection area of the bottom gate electrode are the same.

In one embodiment, the upper surface of the second organic isolation layer is a planar surface; the orthogonal projection area of the second organic isolation layer and the orthogonal projection area of the bottom gate electrode are the same.

In one embodiment, the upper surface of the top gate electrode is a planar surface; the orthogonal projection area of the top gate electrode and the orthogonal projection area of the bottom gate electrode are the same.

In one embodiment, the top gate electrode overlaps the source-drain electrode.

In one embodiment, the dual gate device further comprising:

a passivation layer on the upper surface of the first organic isolation layer away from the substrate and covering the organic semiconductor layer, the second organic isolation layer and the top gate electrode.

In one embodiment, the orthogonal projection area of the passivation layer and the orthogonal projection area of the substrate are the same.

In one embodiment, the substrate is made of poly ethylene naphthalate, polyethylene terephthalate or polyimide; the first metal layer, the second metal layer and the third metal layer are made of any one of gold, sliver, cooper and iron.

Organic thin film transistor (OTFT) of the embodiment of the disclosure adopts the dual gate structure to improve the device characteristic . The embodiment of the disclosure has following beneficial effects, wherein:

1. The dual gate structure reduces the threshold voltage, increases the on-state current and reduces the off-state current;
2. The top gate electrode overlapping the source-drain electrode makes the dual gate device to reduce the device contact resistance and to save the power consumption.

### BRIEF DESCRIPTION OF THE DRAWINGS

In order to more clearly illustrate the prior art or the embodiments or aspects of the practice of the disclosure, the accompanying drawings for illustrating the prior art or the embodiments of the disclosure are briefly described as below. It is apparently that the drawings described below are merely some embodiments of the disclosure, and those skilled in the art may derive other drawings according the drawings described below without creative endeavor.

FIG. 1 is a flow chart of the method of manufacturing the dual gate device according to the first embodiment of the disclosure;

FIG. 2 is a schematic diagram of the partial structure of the dual gate device according to the method of manufacturing showing in FIG. 1;

FIG. 3 is a schematic diagram of the partial structure of the dual gate device according to the method of manufacturing showing in FIG. 1;

FIG. 4 is a schematic diagram of the partial structure of the dual gate device according to the method of manufacturing showing in FIG. 1;

FIG. 5 is a schematic diagram of the partial structure of the dual gate device according to the method of manufacturing showing in FIG. 1;

FIG. 6 is a schematic diagram of the structure of the dual gate device according to the first embodiment of the disclosure;

FIG. 7 is a flow chart of the method of manufacturing the dual gate device according to the second embodiment of the disclosure; and

FIG. 8 is a schematic diagram of the structure of the dual gate device according to the second embodiment of the disclosure.

### DETAILED DESCRIPTION

The following description with reference to the accompanying drawings is provided to clearly and completely explain the exemplary embodiments of the disclosure. It is apparent that the following embodiments are merely some embodiments of the disclosure rather than all embodiments of the disclosure. According to the embodiments in the disclosure, all the other embodiments attainable by those skilled in the art without creative endeavor belong to the protection scope of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that “and/or” refers to and encompasses any and all possible combinations of one or more of the associated listed items. Besides, the descriptions of the embodiments may refer to the accompanying drawings to provide a further understanding of the embodiments of the invention. In the description, relative terms such as “longitudinal”, “lateral”, “front”, “rear”, “right”, “left”, “lower”, “upper”, “horizontal”, “vertical”, “above”, “below”, “up”, “top”, “bottom” as well as derivative thereof (e.g., “horizontally”, “downwardly”, “upwardly”, etc.) should be construed to refer to the orientation as then described or as shown in the drawings under discussion. These relative terms are for convenience of description and do not require that the present disclosure be constructed or operated in a particular orientation.

In the description, terms concerning attachments, coupling and the like, such as “connected” and “interconnected”, refer to a relationship wherein structures are secured or attached to one another through mechanical or electrical connection, or directly or indirectly through intervening structures, unless expressly described otherwise. Specific implications of the above phraseology and terminology may be understood by those skilled in the art according to specific situations.

Further, in the description of the disclosure, unless otherwise specified, “plurality” means two or more. In the present specification, the term “process” encompasses an independent process, as well as a process that cannot be clearly distinguished from another process but yet achieves the expected effect of the process of interest. In the present specification, a numerical range expressed using “to” means a range including the numerical values before and after “to” as the minimum and maximum values, respectively. In the drawings, like constructional elements each displays the same reference numeral.

Photolithography process is a flow for obtaining a final perpetual pattern through the photosensitive material (also known as a photoresist) coated on the surface of the glass, the portions left after the photosensitive material exposed and developed coming into protecting the bottom layer, and then stripping and etching.

Photolithography mask is also known as the photomask. In the entire semiconductor manufacturing process, part of which is a process from the layout to a wafer manufacturing process, also known as the manufacturing of the photomask. This section is the key part of connecting the process and the highest manufacturing cost of the process. This section is also one of the bottlenecks of the minimum line width limitation. The photomask substrate is the ideal photosensitive plate to manufacture the tiny photomask layout. The photomask substrate may be obtained by photolithographic process. The photomask is made by the photomask substrate being etched with the mask pattern. The information of the original pattern of the carrier is passed to the wafer through the exposure process.

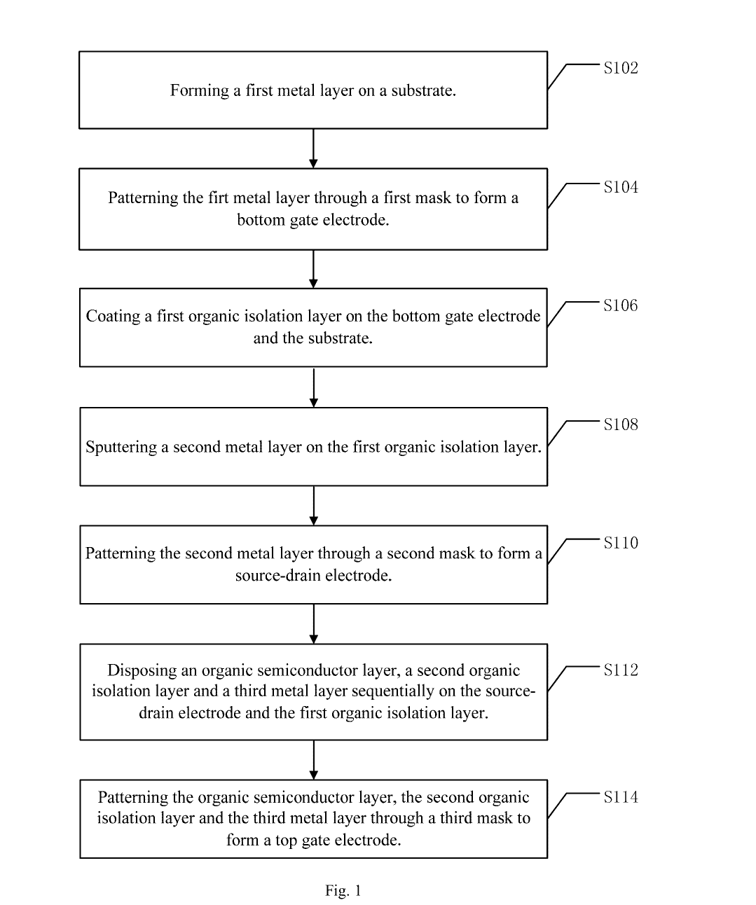

Refer to FIG. 1. FIG. 1 is a flow chart of the method of manufacturing the dual gate device according to the first embodiment of the disclosure. The method of manufacturing comprises the following steps.

Step S102: forming a first metal layer on a substrate.

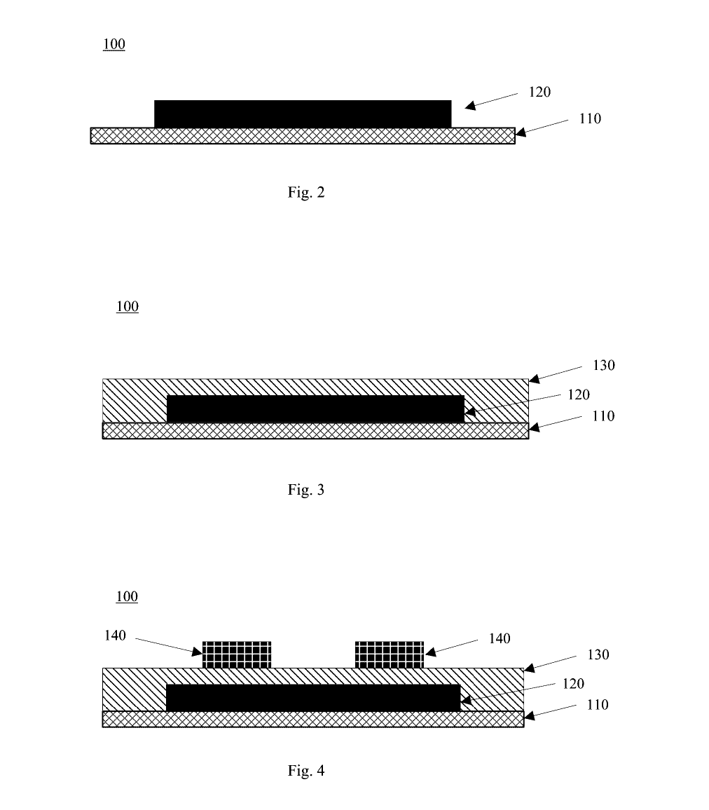

Specifically, as shown in FIG. 2, the substrate 110 can be made of polyethylene naphthalene (PEN), polyethylene terephthalate (PET) or polyimide (PI). The first metal layer 120 is formed on an upper surface of the substrate 110 by sputtering. The first metal layer 120 can be made of, but not limited to, gold, sliver, cooper and iron. Preferably, the first metal layer 120 may be made of gold.

Step S104: patterning the first metal layer through a first mask to form a bottom gate electrode.

Specifically, as shown in FIG. 2, in one embodiment of the disclosure, the first metal layer 120 can be patterned through the first photomask by photolithography process (for example, developing, wet etching, dry etching, etc.). The first metal layer 120 may be treated as the bottom gate electrode 120. The bottom gate electrode 120 is in a middle region of an upper surface of the substrate 110. A plan view of the pattern of the bottom gate electrode 120 can be, but not limited to, a linear pattern, a curve pattern, a polygonal pattern, a circular pattern, an oval pattern, a starlike pattern, and etc. Specific pattern shapes can be determined based on actual usage; the embodiment of the disclosure is not particularly limited to this.

Step S106: coating a first organic isolation layer on the bottom gate electrode and the substrate.

Specifically, as shown in FIG. 3, in one embodiment of the disclosure, the first organic isolation layer 130 is coated on the bottom gate electrode 120 and the substrate 110. The first organic isolation layer 130 covers the bottom gate electrode 120. The upper surface of the first organic isolation layer 130 away from the bottom gate electrode 120 can be a planar surface.

Step S108: sputtering a second metal layer on the first organic isolation layer.

Specifically, the second metal layer is formed on the first organic isolation layer 130 by sputtering. The second metal layer can be made of, but not limited to, gold, sliver, cooper and iron. Preferably, the second metal layer may be made of gold.

Step S110: patterning the second metal layer through a second mask to form a source-drain electrode.

Specifically, as shown in FIG. 4, in one embodiment of the disclosure, the second metal layer can be patterned through the second photomask by photolithography process and formed source-drain electrode 140. The source-drain electrode 140 is on the upper surface of the first organic isolation layer 130. The source-drain electrode 140 is in the region of the surrounding border of the gate electrode 120. The source-drain electrode 140 is in the orthogonal projection area of the bottom gate electrode 120. The source-drain electrode 140 is on the upper surface of the first organic isolation layer 130 and in the region of the surrounding border of the gate electrode 120. A plan view of the pattern of the source-drain electrode 140 can be, but not limited to, a linear pattern, a curve pattern, a polygonal pattern, a circular pattern, an oval pattern, a starlike pattern etc. Specific pattern shapes can be determined based on actual usage; the embodiment of the disclosure is not particularly limited to this.

Step S112: disposing an organic semiconductor layer, a second organic isolation layer and a third metal layer sequentially on the source-drain electrode and the first organic isolation layer.

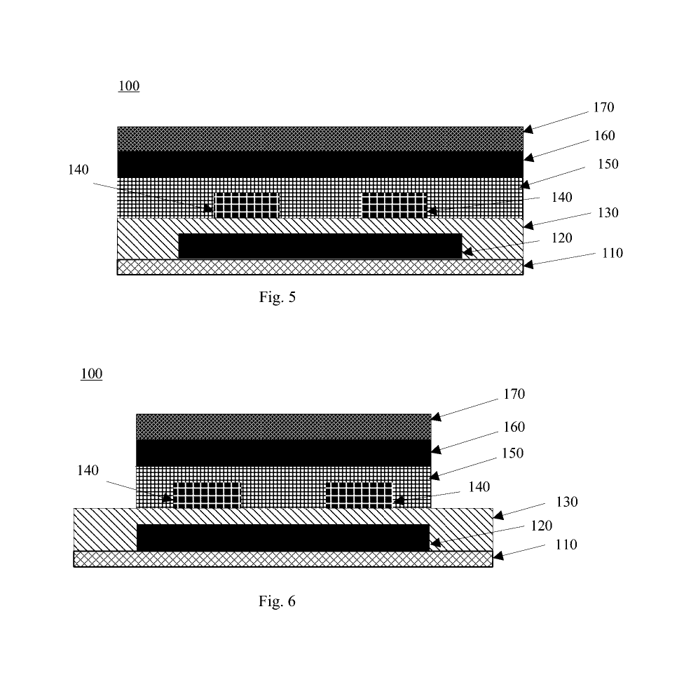

Specifically, as shown in FIG. 5, an organic semiconductor layer 150, a second organic isolation layer 160 and a third metal layer 170 is sequentially disposed on the source-drain electrode 140 and the first organic isolation layer 130. The third metal layer 170 can be made of, but not limited to, gold, sliver, cooper and iron. Preferably, the third metal layer 170 may be made of gold.

Step S114: patterning the organic semiconductor layer, the second organic isolation layer and the third metal layer through a third mask to form a top gate electrode.

Specifically, as shown in FIG. 6, in one embodiment of the disclosure, the organic semiconductor layer 150, the second organic isolation layer 160 and the third metal layer 170 can be patterned through the third photomask by photolithography process (for example, developing, wet etching, dry etching, and etc.). The third metal layer 170 may be treated as the top gate electrode 170. A plan view of the pattern of the top gate electrode 170 can be, but not limited to, a linear pattern, a curve pattern, a polygonal pattern, a circular pattern, an oval pattern, a starlike pattern and etc. Specific pattern shapes can be determined based on actual usage; the embodiment of the disclosure is not particularly limited to this.

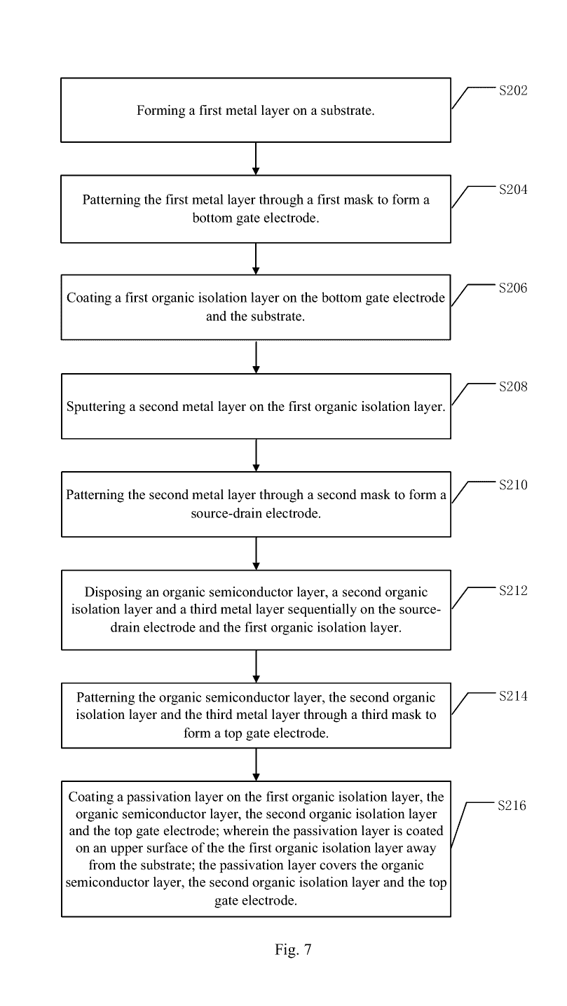

Refer to FIG. 7. FIG. 7 is a flow chart of the method of manufacturing the dual gate device according to the second embodiment of the disclosure. The method comprises:

Step S202: forming a first metal layer on a substrate;

Step S204: patterning the first metal layer through a first mask to form a bottom gate electrode;

Step S206: coating a first organic isolation layer on the bottom gate electrode and the substrate;

Step S208: sputtering a second metal layer on the first organic isolation layer;

Step S210: patterning the second metal layer through a second mask to form a source-drain electrode;

Step S212: disposing an organic semiconductor layer, a second organic isolation layer and a third metal layer sequentially on the source-drain electrode and the first organic isolation layer;

Step S214: patterning the organic semiconductor layer, the second organic isolation layer and the third metal layer through a third mask to form a top gate electrode.

Specifically, step S202 to S214 can refer to step S102 to S114 in the embodiment of the FIG. 1, and thus are not repeated here.

Step S216: coating a passivation layer on the first organic isolation layer, the organic semiconductor layer, the second organic isolation layer and the top gate electrode;

wherein the passivation layer is coated on an upper surface of the first organic isolation layer away from the substrate; the passivation layer covers the organic semiconductor layer, the second organic isolation layer and the top gate electrode.

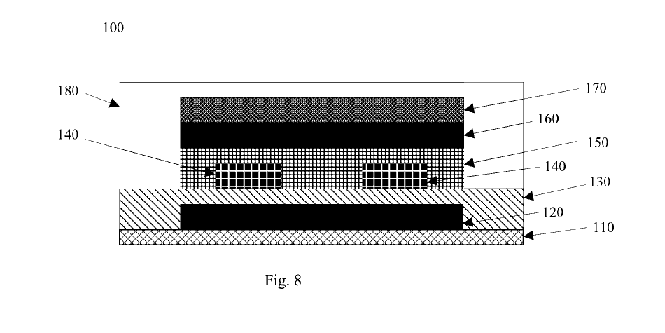

Specifically, as shown in FIG. 8, the first organic isolation layer 130, the organic semiconductor layer 150, the second organic isolation layer 160 and the top gate electrode 170 are coated on the passivation layer 180. In the embodiment of the disclosure, the passivation layer 180 can be an organic glass layer. The passivation layer 180 is on the upper surface of the first organic isolation layer 130 and covers the organic semiconductor layer 150, the second organic isolation layer 160 and the top gate electrode 170. The orthogonal projection area of the passivation layer 180 and the orthogonal projection area of the substrate 110 are the same.

Refer to FIG. 8. FIG. 8 is a schematic of the structure of the dual gate device according to the second embodiment of the disclosure. In the embodiment of the disclosure, the dual gate device comprises a substrate 110, a bottom gate electrode 120, a first organic isolation layer 130, a source-drain electrode 140, an organic semiconductor layer 150, a second organic isolation layer 160, atop gate electrode 170 and a passivation layer 180.

The substrate 110 can be made of polyethylene naphthalene (PEN), polyethylene terephthalate (PET) or polyimide (PI). The first metal layer 120 is formed on the upper surface of the substrate 110 by sputtering. The first metal layer 120 can be made of, but not limited to, gold, sliver, cooper and iron. Preferably, the first metal layer 120 may be made of gold.

The bottom gate electrode 120 is in a middle region of the upper surface of the substrate 110. A plan view of the pattern of the bottom gate electrode 120 can be, but not limited to, a linear pattern, a curve pattern, a polygonal pattern, a circular pattern, an oval pattern, a starlike pattern etc. Specific pattern shapes can be determined based on actual usage; the embodiment of the disclosure is not particularly limited to this.

The first organic isolation layer 130 is on the bottom gate electrode 120 and the substrate 110. The first organic isolation layer 130 covers the bottom gate electrode 120. The upper surface of the first organic isolation layer 130 away from the bottom gate electrode 120 is a planar surface.

The source-drain electrode 140 is on the upper surface of the first organic isolation layer 130. The source-drain electrode 140 is in the orthogonal projection area of the bottom gate electrode 120. The source-drain electrode 140 is in the region of the surrounding border of the gate electrode 120. A plan view of the pattern of the source-drain electrode 140 can be, but not limited to, a linear pattern, a curve pattern, a polygonal pattern, a circular pattern, an oval pattern, a starlike pattern etc. Specific pattern shapes can be determined based on actual usage; the embodiment of the disclosure is not particularly limited to this.

The organic semiconductor layer 150 is located at the upper surface of the first organic isolation layer 130 away from substrate 110. The organic semiconductor layer 150 covers the source-drain electrode 140. The upper surface of the organic semiconductor layer 150 away from the source-drain electrode 140 is a planar surface. The orthogonal projection area of the organic semiconductor layer 150 and the orthogonal projection area of the bottom gate electrode 120 are the same.

The second organic isolation layer 160 is located at the upper surface of the organic semiconductor layer 150 away from substrate 110. The upper surface of the second organic isolation layer 160 away from the source-drain electrode 140 is a planar surface. The orthogonal projection area of the second organic isolation layer 160 and the orthogonal projection area of the bottom gate electrode 120 are the same.

The top gate electrode 170 is located at the upper surface of the second organic isolation layer 160 away from substrate 110. The upper surface of the top gate electrode 170 away from the source-drain electrode 140 is a planar surface. The orthogonal projection area of the top gate electrode 170 and the orthogonal projection area of the bottom gate electrode 120 are the same. A plan view of the pattern of the top gate electrode 170 can be, but not limited to, a linear pattern, a curve pattern, a polygonal pattern, a circular pattern, an oval pattern, a starlike pattern etc. Specific pattern shapes can be determined based on actual usage; the embodiment of the disclosure is not particularly limited to this. The top gate electrode 170 can be made of, but not limited to, gold, sliver, cooper and iron. Preferably, the top gate electrode 170 may be made of gold.

The passivation layer 180 is on the upper surface of the first organic isolation layer 130 away from the substrate 110 and covers the organic semiconductor layer 150, the second organic isolation layer 160 and the top gate electrode 170. In the embodiment of the disclosure, the passivation layer 180 is an organic glass layer. The orthogonal projection area of the passivation layer 180 and the orthogonal projection area of the substrate 110 are the same.

It is understood that the dual gate device as shown in FIG. 8 is made according to the method of manufacturing the dual gate device shown in FIG. 1 or 7, and thus the description is not repeated here.

In summary, the embodiment of the disclosure provides a method of manufacturing the dual gate device and a dual gate device. Organic thin film transistor (OTFT) adopts the dual gate structure to improve the device characteristic. The embodiment of the disclosure has following beneficial effects, wherein:

The dual gate structure reduces the threshold voltage, increases the on-state current and reduces the off-state current;

The top gate electrode overlapping the source-drain electrode makes the dual gate device to reduce the device contact resistance and to save the power consumption.

Those of ordinary skill will be understood to achieve the above-described embodiments of the method in all or part of the process, can be achieved through a computer program instructing relevant hardware. The program may be stored in a computer readable storage medium the program is executed, the steps of the method as the above embodiments. Wherein the storage medium may be a magnetic disk, an optical disk, read-only memory (Read-Only Memory, ROM), or random access memory (Random Access Memory, RAM) and the like.

Reference throughout this specification to “an embodiment”, “some embodiments”, “an embodiment”, “an example”, “a specific examples”, or “some examples” means that a particular feature, structure, material, or characteristic described in connection with the embodiment or example is included in at least an embodiment or example of the disclosure. Thus, the appearances of the phrases such as “in some embodiments”, “in an embodiment”, “in an embodiment”, “an example”, “a specific examples”, or “some examples” in various places throughout this specification are not necessarily referring to the same embodiment or example of the disclosure. Furthermore, the particular features, structures, materials, or characteristics may be combined in any suitable manner in one or more embodiments or examples.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. A method of manufacturing a dual gate device, comprising:
forming a first metal layer on a substrate;
patterning the first metal layer through a first mask to form a bottom gate electrode;
coating a first organic isolation layer on the bottom gate electrode and the substrate;
sputtering a second metal layer on the first organic isolation layer;
patterning the second metal layer through a second mask to form a source-drain electrode;
disposing an organic semiconductor layer, a second organic isolation layer and a third metal layer sequentially on the source-drain electrode and the first organic isolation layer; and
patterning the organic semiconductor layer, the second organic isolation layer and the third metal layer through a third mask to form a top gate electrode.

2. The method of manufacturing the dual gate device according to claim 1, wherein the first organic isolation layer covers the bottom gate electrode; the organic semiconductor layer covers the source-drain electrode; the top gate electrode overlaps the source-drain electrode.

3. The method of manufacturing the dual gate device according to claim 1, wherein the source-drain electrode is in the orthogonal projection area of the bottom gate electrode.

4. The method of manufacturing the dual gate device according to claim 1, wherein the bottom gate electrode is in a middle region of an upper surface of the substrate.

5. The method of manufacturing the dual gate device according to claim 1, wherein a surface of the organic semiconductor layer away from the source-drain electrode is a planar surface.

6. The method of manufacturing the dual gate device according to claim 1, wherein the top gate electrode overlaps the source-drain electrode.

7. The method of manufacturing the dual gate device according to claim 1 further comprising:
coating a passivation layer on the first organic isolation layer, the organic semiconductor layer, the second organic isolation layer and the top gate electrode; wherein the passivation layer is coated on an upper surface of the first organic isolation layer away from the substrate; the passivation layer covers the organic semiconductor layer, the second organic isolation layer and the top gate electrode.

8. The method of manufacturing the dual gate device according to claim 1, wherein the orthogonal projection area of the passivation layer and the orthogonal projection area of the substrate are the same.

9. The method of manufacturing the dual gate device according to claim 1, wherein the substrate is made of poly ethylene naphthalate, polyethylene terephthalate or polyimide; the first metal layer, the second metal layer and the third metal layer are made of any one of gold, sliver, cooper and iron.

10. A dual gate device, comprising:
a substrate;
a bottom gate electrode located at a upper surface of the substrate;
a first organic isolation layer located at the upper surface of the substrate and covering the bottom gate electrode;
a source-drain electrode located at an upper surface of the first organic isolation layer of the substrate;
an organic semiconductor layer located at the upper surface of the first organic isolation layer of the substrate and covering the source-drain electrode;
a second organic isolation layer located at an upper surface of the organic semiconductor layer of the substrate; and
a top gate electrode located at an upper surface of the second organic semiconductor layer of the substrate.

11. The dual gate device according to claim 10, wherein the source-drain electrode are in the orthogonal projection area of the bottom gate electrode; the upper surface of the organic semiconductor layer is a planar surface.

12. The dual gate device according to claim 11, wherein the orthogonal projection area of the organic semiconductor layer and the orthogonal projection area of the bottom gate electrode are the same.

13. The dual gate device according to claim 11, wherein the upper surface of the second organic isolation layer is a planar surface; the orthogonal projection area of the second organic isolation layer and the orthogonal projection area of the bottom gate electrode are the same.

14. The dual gate device according to claim 13, wherein the upper surface of the top gate electrode is a planar surface; the orthogonal projection area of the top gate electrode and the orthogonal projection area of the bottom gate electrode are the same.

15. The dual gate device according to claim 10, wherein the top gate electrode overlaps the source-drain electrode.

16. The dual gate device according to claim 10 further comprising:
a passivation layer on the upper surface of the first organic isolation layer away from the substrate and covering the organic semiconductor layer, the second organic isolation layer and the top gate electrode.

17. The dual gate device according to claim 16, wherein the orthogonal projection area of the passivation layer and the orthogonal projection area of the substrate are the same.

18. The dual gate device according to claim 10, wherein the substrate is made of poly ethylene naphthalate, polyethylene terephthalate or polyimide; the first metal layer, the second metal layer and the third metal layer are made of any one of gold, sliver, cooper and iron.
